(19) United States
(12) Patent Application Publication
(10) Pub. No.: US 2007/0243708 A1
(43) Pub. Date: Oct. 18, 2007

(54) Manufacturing method for an integrated semiconductor contact structure having an improved aluminum fill

(76) Inventors: Jens Hahn, Dresden (DE); Tom Richter, Dresden (DE); Detlef Weber, Hermsdorf (DE); Chung-Hsin Lin, Dresden (DE)

Correspondence Address: JENKINS, WILSON, TAYLOR & HUNT, P. A., SUITE 1200, UNIVERSITY TOWER, 3100 TOWER BOULEVARD, DURHAM, NC, 27707, US

(21) Appl. No.: 11/402,675

(22) Filed: Apr. 12, 2006

(51) Int. Cl. H01L 21/4763; H01L 21/44

(52) U.S. Cl. 438/688; 438/622

(57) ABSTRACT

The present invention provides a manufacturing method for an integrated semiconductor contact structure having an improved Aluminum fill comprising the steps of: forming contact holes in an insulation layer provided on a wafer, said contact holes having a respective bottom and respective sidewalls, said bottoms including a respective conductive area; introducing said wafer into a first PVD deposition chamber, said first PVD deposition chamber including a wafer bias means; and cold depositing a first Aluminum layer on the wafer in said first PVD deposition chamber, said first Aluminum layer covering said bottoms and said sidewalls of said contact holes and forming a seed layer; wherein during said step of cold depositing said first Aluminum layer on the wafer in said first PVD deposition chamber said wafer bias means is set to a bias in the range between 20 W and 700 W or −50 V to −800 V.

### BACKGROUND OF THE INVENTION

1. Field of the Invention

The present invention relates to a manufacturing method for an integrated semiconductor contact structure having an improved Aluminum fill.

2. Description of the Related Art

Although in principle applicable to arbitrary integrated semiconductor contact structures, the following invention and the underlying problems will be explained with respect to integrated DRAM memory circuits in silicon technology.

Integrated semiconductor circuits, such as DRAM memory circuits or logic device circuits, usually have a plurality of structured metallization levels which are mutually electrically connected via metal contacts (also called interconnects) which extend through contact holes (also called vias). The vias are holes in interlevel dielectric layers which electrically isolate adjacent metallization levels. Normally the vias are formed by standard lithography processes followed by reactive ion etching or similar processes.

Aluminum is preferentially used as material for both the metallization levels and the contacts. Due to the ongoing downskaling process of integrated circuit technologies, the requirements for line resistance, contact-resistance, void-free contact filling and metal reliability, become more and more demanding. DRAM memory circuits in silicon technology appear to reach the limit for aluminum or aluminum/copper PVD metallization with 70 nm technology. From the economic and integration point of view there is a great interest to defer the switchover to copper technology as far as possible, because for feature sizes below 100 nm the copper line resistance increases strongly compared to the aluminum line resistance.

DRAM memory circuit interconnect technology reflects the most aggressive metal pitch and the highest aspect ratio contacts. Therefore, the capability for aluminum contact processing must be continuously improved and extended.

US 2004/0242007 A1 discloses a process for producing aluminum filled contact holes in a wafer. The process uses a coating installation that includes a plurality of vacuum-processing chambers that are coupled to another via at least one transfer chamber with an associated handler for transferring the wafer. The process comprises the steps of forming the contact holes; depositing a barrier layer; cooling the wafer to ambient temperature; cold aluminum PVD coating the wafer, the coating being carried out in a PVD aluminum electrostatic chuck chamber; heating the wafer to a temperature of less than about 450° C.; and carrying out a hot aluminum PVD deposition in the PVD aluminum electrostatic chuck chamber.

The problems which are connected with the process known from US 2004/0242007 A1 and similar aluminum infill processes for contact holes will be illustrated with reference to FIG. 3a-3c which are partial cross-sectional views of a semiconductor wafer 1 and show a contact structure formed by a conventional manufacturing method for an integrated semiconductor contact structure.

The semiconductor wafer 1 includes a (not shown) semiconductor memory chip, such as a DRAM memory chip, which is not shown in FIG. 3a-c. The partial cross-sectional views of FIGS. 3a-c only show a conductive metal line M1 of a first metallization level, an interlevel dielectric layer ILD which separates the first metallization level from the second metallization level, and a contact hole V which has been formed in the interlevel dielectric layer ILD to expose the conductive metal line M1 at the bottom of the contact hole V. The contact hole can be formed in tapered (as shown) or straight geometry.

As shown in FIG. 3b, a liner layer LI made of titanium is then formed over the interlevel dielectric layer ILD and in the contact hole V. This liner layer LI is required for filling gaps and voids forming a barrier layer and realizing sufficient metal adhesion on the surface of the interlevel dielectric layer ILD.

Thereafter, a first aluminum layer A1 is cold deposited on the bottom and the sidewalls of the contact hole V and on the interlevel dielectric layer ILD using a sputter chamber using a high power sputtering process at low temperature such as room temperature. This first aluminum layer A1 is a fine grained conformal seed-layer for a subsequent aluminum plugged fill-in process.

As illustrated in FIG. 3b, the roughness of the surface OS of the first aluminum layer A1 is considerable. Although the roughness is sufficient to make reactive ion etching patterning still possible, the inventors of the present invention found out that the roughness obstructs the hot infill of a second aluminum layer A2 which will be explained with respect to FIG. 3c.

The second aluminum layer A2 is hot deposited on the first aluminum layer A1 at a temperature of about 400° C. on a hot chuck. This causes reflow of the second aluminum layer A2 in order to fill the contact hole V. As illustrated in the partial enhancement of FIG. 3c, clusters CL and/or surface atoms of aluminum have to hop over barriers formed by the rough surface OS of the first aluminum layer A1 in order to fill the contact hole V. This hopping becomes a limiting factor for the filling of contact holes V which have high aspect ratios, such as 2-5, and a diameter of 100 nm and less. For this high aspect ratios and small diameters, voids will develop in the second aluminum layer A1 within the contact hole V and lead to undesired mechanical and electrical drawbacks.

### SUMMARY OF THE INVENTION

According to a first aspect of the invention, a manufacturing method for an integrated semiconductor contact structure is provided which comprises the steps of: forming contact holes in an insulation layer provided on a wafer, said contact holes having a respective bottom and respective sidewalls, said bottoms including a respective conductive area; introducing said wafer into a first PVD deposition chamber, said first PVD deposition chamber including a wafer bias means; and cold depositing a first Aluminum layer on the wafer in said first PVD deposition chamber, said first Aluminum layer covering said bottoms and said sidewalls of said contact holes and forming a seed layer; wherein during said step of cold depositing said first Aluminum layer on the wafer in said first PVD deposition chamber said wafer bias means is set to a bias in the range between 20 W and 700 W or −50 V to −800 V.

According to a second aspect of the invention, a manufacturing method for an integrated semiconductor contact structure is provides which comprises the steps of: forming contact holes in an insulation layer of a semiconductor structure, said contact holes having a respective bottom and respective sidewalls, said bottoms including a respective conductive area; cold depositing a first Aluminum layer on said semiconductor structure, said first Aluminum layer covering said bottoms and said sidewalls of said contact holes and forming a seed layer; wherein during said step of cold depositing said first Aluminum layer a bias in the range between 20 W and 700 W or −50 V to −800 V is applied to said semiconductor structure.

According to a third aspect of the invention, a manufacturing method for an integrated semiconductor contact structure is provides which comprises the steps of: forming holes in an insulation layer of a semiconductor structure, said holes having a respective bottom and respective sidewalls; cold depositing a first Aluminum layer on said semiconductor structure, said first Aluminum layer covering said bottoms and said sidewalls of said holes and forming a seed layer; wherein during said step of cold depositing said first Aluminum layer a bias in the range between 20 W and 700 W or −50 V to −800 V is applied to said semiconductor structure.

The methods according to the first, second and and third aspect of the present invention provide an smoother surface of the first aluminum layer. They increase the stress migration reliability of chain structures. Minimal costs of adding an RF or DC generator to the PVD deposition-chamber are only involved. The methods according to the invention also provide an improved <111> orientation of the aluminum in the first aluminum layer. The thermal bugdet for the infill of a following hot aluminum infill process may be reduced for the same dimensions of the contact holes or may be kept for smaller dimensions of the contact holes.

Preferred embodiments are listed in the respective dependent claims.

According to a preferred embodiment, a step of hot depositing a second Aluminum layer on the first Aluminum layer at a temperature greater about 300° C. is performed, said second Aluminum layer filling said contact holes without a void.

According to another preferred embodiment, a step of cleaning said contact holes is performed.

According to another preferred embodiment, a step depositing a liner layer is performed, said liner layer covering said bottoms and said sidewalls of said contact holes and forming an Aluminum barrier layer.

According to another preferred embodiment, said liner layer is made of Titanium.

According to another preferred embodiment, said insulation layer is a inter-level dielectric layer which provides an insulation between two metallization levels.

According to another preferred embodiment, said insulation layer is a dielectric layer which provides an insulation between a metallization level and a wafer level.

According to another preferred embodiment, said contact hole has a aspect ratio between 2 and 5.

According to another preferred embodiment, said wafer bias amouts to about 200 W or −250 V.

According to another preferred embodiment, said step of cold depositing said first Aluminum layer is performed at about room temperature.

According to another preferred embodiment, said step of hot depositing said second Aluminum layer is performed at a temperature between about 300° C. and 400° C.

### DESCRIPTION OF THE DRAWINGS

In the Figures:

FIG. 1a-c show schematic cross-sections of contact structure formed by a manufacturing method for an integrated semiconductor contact structure according to an embodiment of the present invention;

FIG. 2 shows a schematic diagram of a PVD chamber used in a manufacturing method for an integrated semiconductor contact structure according to said embodiment of the present invention; and

FIG. 3a-c show schematic cross-sections of contact structure formed by a conventional manufacturing method for an integrated semiconductor contact structure.

In the Figures, identical reference signs denote equivalent or functionally equivalent components.

### DETAILED DESCRIPTION OF THE PREFERRED EMBODIMENTS

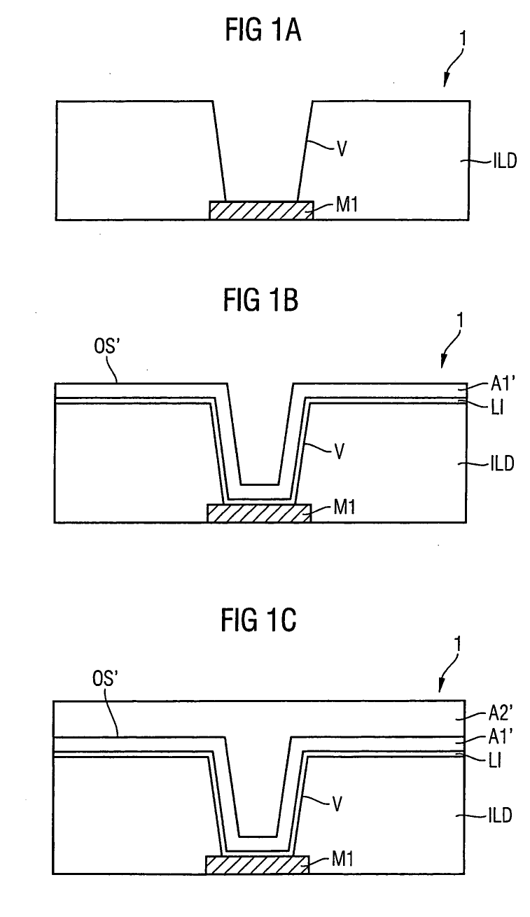

FIGS. 1a-c show partial cross-sectional views of semiconductor wafer 1 for illustrating a contact structure formed by a manufacturing method for an integrated semiconductor contact structure according to an embodiment of the present invention.

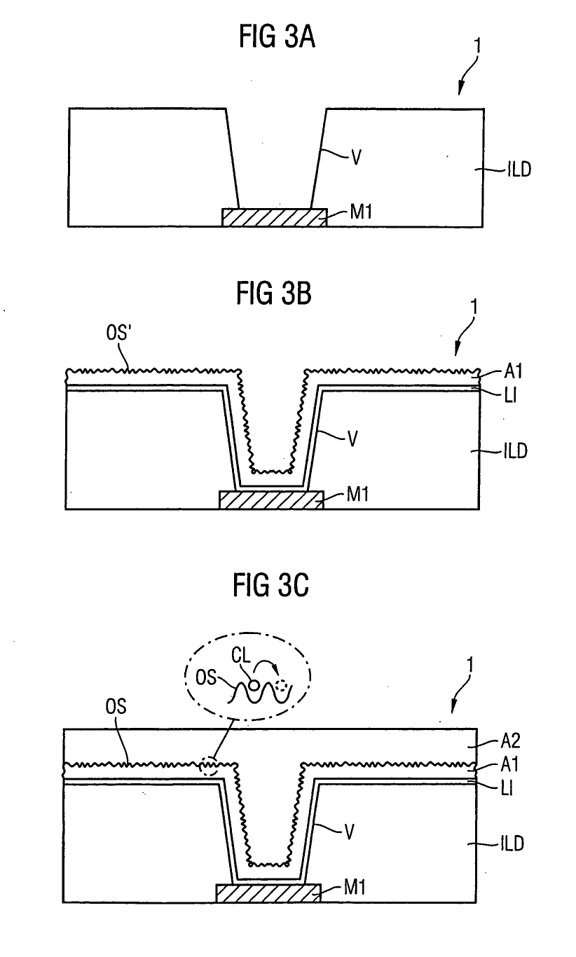

As depicted in FIG. 1a, conductive metal line Ml of the first metallization level is exposed by a contact hole V formed in the overlying interlevel dielectric layer ILD. This process state corresponds to the process state explained above with respect to FIG. 3a. In the shown embodiment, the contact hole V has a diameter of 100 nm and an aspect ratio of 1. Thereafter, a step of cleaning said contact holes using argon sputtering may be performed optionally.

Thereafter, as illustrated in FIG. 1b, the liner layer LI of titanium having a thickness of about 10 nm is formed in the contact hole V and on top of the surrounding interlevel dielectric layer ILD in a conventional PVD process which is carried out in a specially designated PVD chamber.

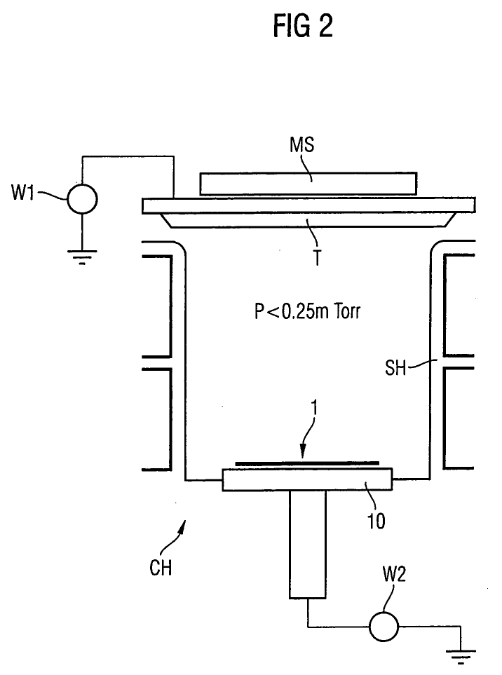

Then, the wafer 1 is transferred into the long-throw PVD chamber CH which is illustrated in FIG. 2. This PVD chamber CH includes a cold chuck 10 on which the wafer 1 is placed.

The chamber walls are covered by shielding means SH. Located above the wafer 1 is an aluminum target T on which a magnetron MS is located. Reference sign W1 denotes high DC power source which generates power of more than 20 kW for the magnetron MS. Reference sign W2 denotes a wafer bias generator which generates an electrostatic potential on the chuck 10 and therefore on the wafer 1 which gives the sputtered aluminum ions and Argon ions a preferential direction and increased energy and momentum transfer to the surface when impinging on the surface of the wafer 1.

The process pressure in the shown long-throw PVD chamber CH during the cold aluminum deposition process is maintained below 1 mTorr, preferably 0.25 mTorr.

In contrast to the conventional process explained above in connection with FIGS. 3a-c, the process according to the preferred embodiment of the invention uses a bias between 20 W and 700 W, preferably 200 W, for cold depositing a first aluminum layer A1′ on the bottom and the side-walls of the contact-hole V and on the top of the inter-level dielectric layer ILD at room temperature. In units of Volts this approximately corresponds to a voltage range of −50 V to −800 V for this PVD chamber.

The bias in the above given range helps to remove the undesired roughness of the surface of the first aluminum layer A1′ which conventionally impeded the later hot aluminum infill process step. This is because the bias improves the orientation of the aluminum grains.

However, it is quite remarkable that when applying a bias in the above given range and for a thickness of the first aluminum layer A1′ up to about 200 nm and corresponding contact hole diameter, no deterioration of the sidewall coverage of the contact hole V was observed.

Conventionally, significant resputtering effects would have been exspected, i.e. aluminum ions on the bottom of the contact hole V are removed and trapped again on the upper regions of the sidewalls which leads to remarkable inhomogeneities of the bottom and sidewall coverage and would be connected with voids after the following hot aluminum infill step.

However, the inventors found that for the above given bias range and up to a certain thickness of the cold sputtered first aluminum layer A1′, such an inhomogeneity effects do not occur. This maybe explained by the fact that resputtering effects only occur for biases and thicknesses above certain critical values. At values below such critical values other effects appear to be predominant, such as cluster bonding effects or similar.

The unexpected experimental results of the present inventors show that aluminum is still an attractive metallization for producing metal interconnects in vias with an aspect ratio between 2 and 5 for DRAM or other microlectronic applications at 70 nm technology nodes and even below.

Then, the wafer 1 is transferred into another PVD chamber which is not illustrated here and which includes a hot chuck on which the wafer 1 is placed. Heating of chuck is performed by not shown regulation system, f.e. using electrical heating and fluid cooling.

The second aluminum layer A2′ is hot deposited on the first aluminum layer A1′ at a temperature greater than about 300° C. and lower than about 400° C. on said hot chuck. This causes reflow of the second aluminum layer A2′ in order to fill the contact hole V without any voids.

It should be mentioned that for the hot deposition of the second aluminum layer A2′ always a compromise between too low temperature and too high temperature has to be found. If the temperature is too low, the danger of voids increases, and if the temperature is too high, the roughness of the second aluminum layer A2′ increases which leads to problems for the following lithographic structuring. In the particular example, 400° C. were an excellent tradeoff.

Particularly, the present invention makes it possible to reduce the thermal budget for the infill of the second aluminum layer A2′, if the same dimensions of the contact holes are considered, here for example 70 nm technology.

In other words, when using the method of the invention for 70 nm technology, the temperature could be reduced to about 350° C. while retaining a void-less infill of hot aluminum. When using the method of the invention for 50 nm technology, the dimensions of the contact hole could be reduced but the temperature could be kept at 400° C. while maintaining an acceptable roughness for structuring the overlying second metallization level formed by the hot aluminum layer A2′.

Although the present invention has been described with reference to a preferred embodiment, it is not limited thereto, but can be modified in various manners which are obvious for a person skilled in the art. Thus, it is intended that the present invention is only limited by the scope of the claims attached herewith.

Although the above-described preferred embodiment uses a liner layer made of titanium, the invention is not restricted thereto. For appropriate structures the liner layer may be made of another material, such as TiN or a similar material or may be even skipped. Moreover, although the first and second aluminum depositions were performed in different process chambers, they could also be performed in the same process chamber.

Also, the contacts manufactured according to the method of the present invention are not limited to the connection of the first and second metallization level, but can be applied for any two metallization levels and even for the connection between the wafer and the first metallization level.

Although the above-described preferred embodiment uses a pure aluminum PVD process, also an aluminum/copper(0.5%) or aluminum/silicon (1%) process or a similar process may be used, which for the sake of simplictiy should all be understood as an aluminum PVD deposition process herein.

We claim as our invention:

1. A manufacturing method for an integrated semiconductor contact structure comprising the steps of:
forming contact holes in an insulation layer provided on a wafer, said contact holes having a respective bottom and respective sidewalls, said bottoms including a respective conductive area;
introducing said wafer into a first PVD deposition chamber, said first PVD deposition chamber including a wafer bias means; and
cold depositing a first Aluminum layer on the wafer in said first PVD deposition chamber, said first Aluminum layer covering said bottoms and said sidewalls of said contact holes and forming a seed layer;
wherein during said step of cold depositing said first Aluminum layer on the wafer in said first PVD deposition chamber said wafer bias means is set to a bias in the range between 20 W and 700 W or −50 V to −800 V.

2. The method according to claim 1, further comprising the steps of:
transferring said wafer into a second PVD deposition chamber, said second PVD deposition chamber including a wafer chuck; and
hot depositing a second Aluminum layer on the first Aluminum layer in said second PVD deposition chamber, said wafer being brought in thermal contact with said chuck, said chuck being at a temperature greater about 300° C., said second Aluminum layer filling said contact holes without a void.

3. The method according to claim 1, further comprising the step of cleaning said contact holes.

4. The method according to claim 1, further comprising the step depositing a liner layer on said wafer in a third PVD deposition chamber, said liner layer covering said bottoms and said sidewalls of said contact holes and forming an Aluminum barrier layer.

5. The method according to claim 4, wherein said liner layer is made of Titanium.

6. The method according to claim 1, wherein said insulation layer is a inter-level dielectric layer which provides an insulation between two metallization levels.

7. The method according to claim 1, wherein said insulation layer is a dielectric layer which provides an insulation between a metallization level and a wafer level.

8. The method according to claim 1, wherein said contact hole has a aspect ratio beween 2 and 5.

9. The method according to claim 1, wherein said wafer bias means is set to a bias of about 200 W or −250 V.

10. The method according to claim 1, wherein said step of cold depositing said first Aluminum layer on the wafer in said first PVD deposition chamber is performed at about room temperature.

11. The method according to claim 2, wherein said step of hot depositing said second Aluminum layer on the first Aluminum layer in said second PVD deposition chamber is performed at a temperature between about 300° C. 25 and 400° C.

12. A manufacturing method for an integrated semiconductor contact structure comprising the steps of:
forming contact holes in an insulation layer of a semiconductor structure, said contact holes having a respective bottom and respective sidewalls, said bottoms including a respective conductive area;
cold depositing a first Aluminum layer on said semiconductor structure, said first Aluminum layer covering said bottoms and said sidewalls of said contact holes and forming a seed layer;
wherein during said step of cold depositing said first Aluminum layer a bias in the range between 20 W and 700 W or −50 V to −800 V is applied to said semiconductor structure.

13. The method according to claim 12, further comprising the steps of:
hot depositing a second Aluminum layer on the first Aluminum layer at a temperature greater about 300° C., said second Aluminum layer filling said contact holes without a void.

14. The method according to claim 12, further comprising the step of cleaning said contact holes.

15. The method according to claim 12, further comprising the step depositing a liner layer on said semiconductor structure, said liner layer covering said bottoms and said sidewalls of said contact holes and forming an Aluminum barrier layer.

16. The method according to claim 15, wherein said liner layer is made of Titanium.

17. The method according to claim 12, wherein said insulation layer is a interlevel dielectric layer which provides an insulation between two metallization levels.

18. The method according to claim 12, wherein said insulation layer is a di-electric layer which provides an insulation between a metallization level and a wafer level.

19. The method according to claim 12, wherein said contact hole has a aspect ratio beween 2 and 5.

20. The method according to claim 12, wherein said wafer bias amouts to about 200 W or −250 V.

21. The method according to claim 12, wherein said step of cold depositing said first Aluminum layer is performed at about room temperature.

22. The method according to claim 13, wherein said step of hot depositing said second Aluminum layer is performed at a temperature between about 300° C. and 400° C.

23. A manufacturing method for an integrated semiconductor structure comprising the steps of:
forming holes in an insulation layer of a semiconductor structure, said holes having a respective bottom and respective sidewalls;
cold depositing a first Aluminum layer on said semiconductor structure, said first Aluminum layer covering said bottoms and said sidewalls of said holes and forming a seed layer;
wherein during said step of cold depositing said first Aluminum layer a bias in the range between 20 W and 700 W or −50 V to −800 V is applied to said semiconductor structure.

24. The method according to claim 23, further comprising the steps of:
hot depositing a second Aluminum layer on the first Aluminum layer at a temperature greater about 300° C., said second Aluminum layer filling said holes without a void.
